(19) United States
(12) Patent Application Publication
(10) Pub. No.: US 2014/0027145 A1
(43) Pub. Date: Jan. 30, 2014

(54) ELECTRONIC DEVICE ENCLOSURE

(71) Applicants: Hon Hai Precision Industry Co., Ltd., New Taipei (TW); Hong Fu Jin Precision Industry (ShenZhen) Co., Ltd., Shenzhen (CN)

(72) Inventor: HAI-TAO GONG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/893,332

(22) Filed: May 13, 2013

(30) Foreign Application Priority Data
Jul. 27, 2012 (CN) 2012102629998

(51) Int. Cl. H05K 5/00

(52) U.S. Cl. CPC H05K 5/0004
USPC 174/66

(57) ABSTRACT

An electronic device enclosure includes a base, a bezel, and a clasping member. The base includes a front panel. A through hole is defined in the front panel. The bezel includes a clipping portion. The clipping portion includes a connecting arm, a first hook, and a second hook. The clasping member defines a receiving opening with a first edge and a second edge. The clipping portion extends through the through hole and the receiving opening. The clasping member is located relative to the front panel in a first position and a second position, in the first position, the first hook is engaged with the first edge. In the second position, the second hook is engaged with the second edge.

### BACKGROUND

1. Technical Field

The present disclosure relates to enclosures, and more particularly to an electronic device enclosure for securing a bezel to a rear plate.

2. Description of Related Art

An electronic device enclosure, such as a personal computer case, may include a base and a bezel secured to the base with a plurality of screws. Using screws is very laborious and time-consuming. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device enclosure in accordance with an embodiment.

FIG. 2 is similar to FIG. 1, but viewed a different aspect.

FIG. 3 is an assembled view of the electronic device enclosure in FIG. 2, and shows the bezel in an open position.

FIG. 4 is an enlarged view of a circle portion IV of FIG. 1.

FIG. 5 is similar to FIG. 3, but shows the bezel in a locked position.

FIG. 6 is similar to FIG. 1, but viewed in a different aspect.

FIG. 7 is similar to FIG. 5, but shows a clipping member in a different location.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

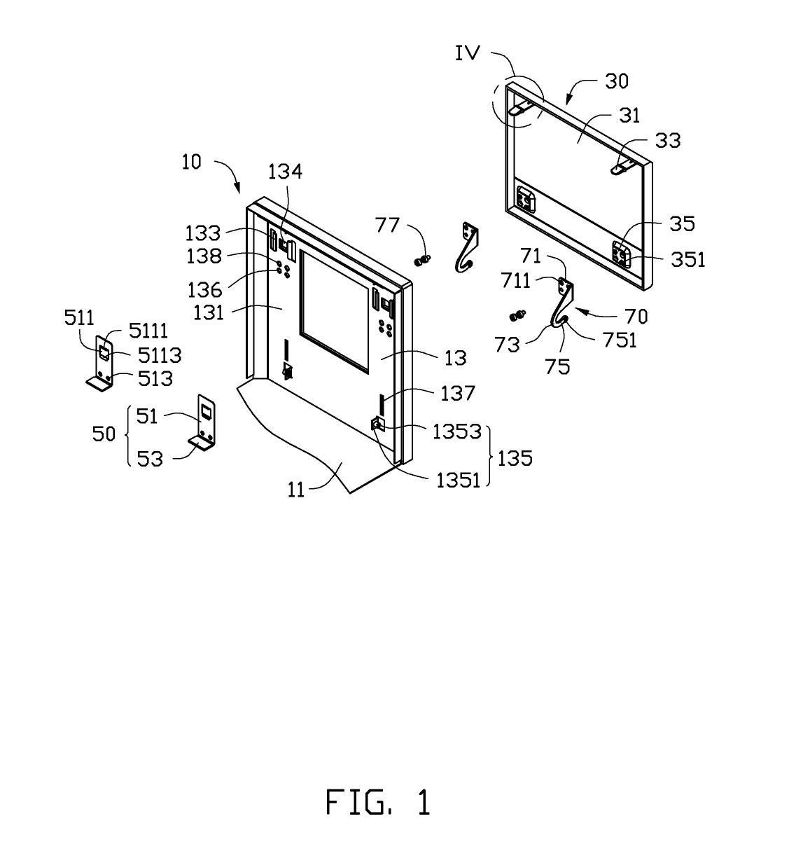

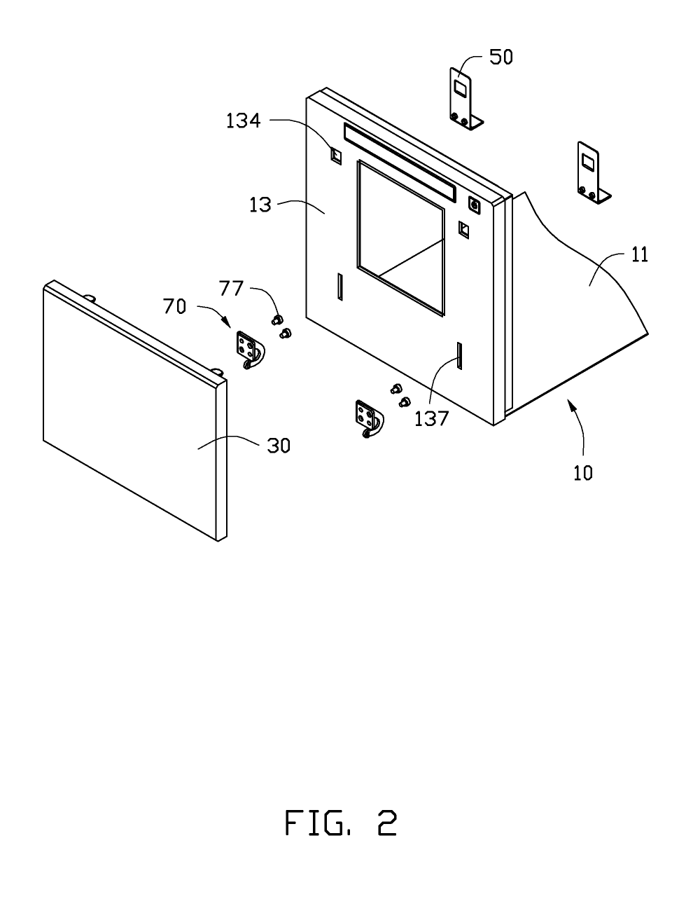

FIGS. 1-2 illustrate an electronic device enclosure in accordance with an embodiment. The electronic device enclosure includes a base 10, a bezel 30, and two clasping members 50. In one embodiment, the electronic device enclosure is a personal computer chassis or a server chassis.

The base 10 comprises a bottom panel 11 and a front panel 13 substantially perpendicular to the bottom panel 11. The front panel 13 comprises a main body 131, two pairs of positioning pieces 133, and two pivoting portions 135. The two pairs of positioning pieces 133 and the two pivoting portions 135 extend from an inner surface of the main body 131. Two through holes 134 are defined in the main body 131, and each of the two through holes 134 is located between each of the two pairs of positioning pieces 133. Two first mounting holes 136, below each of the two pairs of positioning pieces 133, and two second mounting holes 138, above the two first mounting holes 136, are defined in the main body 131. Two mounting slots 137 are defined in the main body 131. Each of the two mounting slots 137 is located above each of the two pivoting portions 135. Each of the two pivoting portions 135 comprises a pivoting piece 1351 substantially perpendicularly extending from the main body 131 and a pivoting post 1353 connected to the pivoting piece 1351.

The bezel 30 comprises a main body 31, two clipping portions 33 and two mounting portions 35. The two clipping portions 33 and the two mounting portions 35 extend from the main body 31. Four mounting holes 351 are defined in each of the two mounting portions 35.

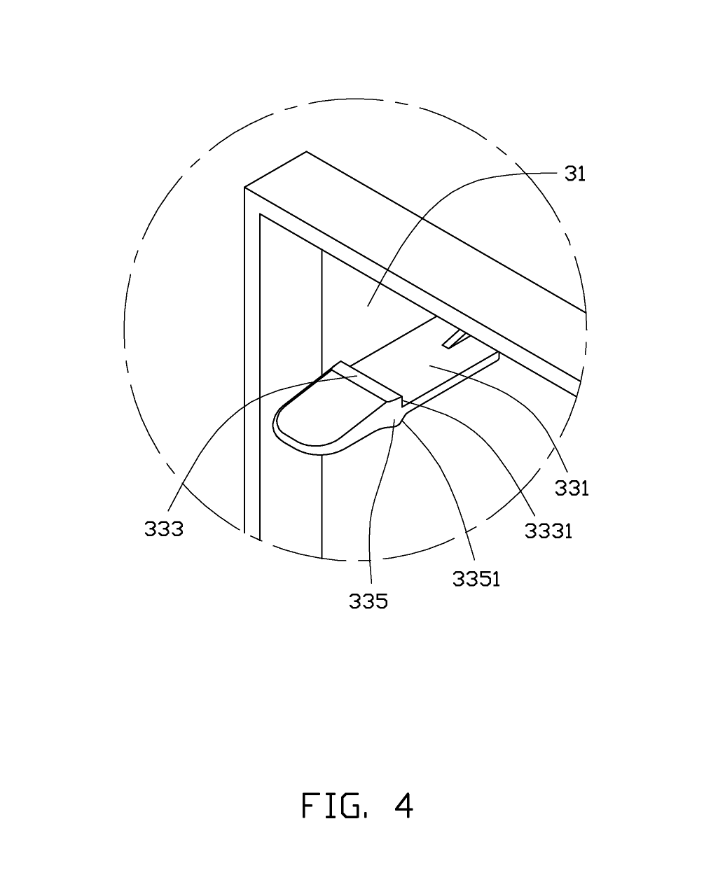

FIG. 4 illustrates an enlarge view of each of the two clipping portions 33. The clipping portion 33 comprises a connecting arm 331 extending from the main body 31, a first hook 333 protruding from a top surface of the connecting arm 331, and a second hook 335 protruding from a bottom surface of the connecting arm 331. The first hook 333 comprises a first clipping surface 3331. The second hook 335 comprises a second clipping surface 3351. In one embodiment, the first clipping surface 3331 is substantially parallel to the main body 131, and the second clipping surface 3351 is an arcuate.

Each of the two rotating members 70, configured to be secured to the bezel 30 a and the base 10. Each of the two rotating members 70 comprises a securing piece 71, a connecting portion 73 extending from the securing piece 71, and a rotating portion 75 extending from the connecting portion 73. Four securing holes 711, corresponding to the four mounting holes 351, are defined in the securing piece 71. A rotating hole 751 is defined in the rotating portion 75.

Each of the two clasping members 50 comprises a mounting piece 51 and an operating portion 53 connected to the mounting piece 51. In one embodiment, the operating portion 53 is substantially perpendicular to the mounting piece 51. A receiving opening 511 and two fixing holes 513 are defined in the mounting piece 51. The receiving opening 511 comprises a first edge 5111 and a second edge 5113 opposite to the first edge 5111. The two fixing holes 513 are aligned with the two first mounting holes 136 or the two second mounting holes 138.

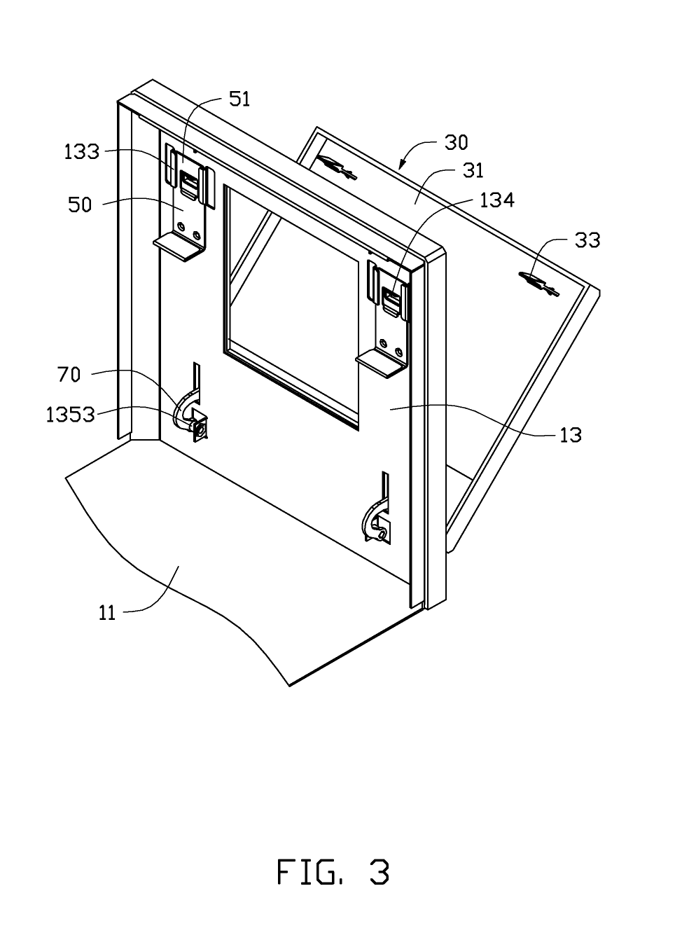

FIG. 3 shows that in assembly, the two securing holes 711 of each of the two rotating members 70 are aligned with two mounting holes 351 of each of the two mounting portions 35. Two mounting members 77, such as screws, are engaged in the two securing holes 711 and the two mounting holes 351. Thus, the two rotating members 70 are secured to the bezel 30. Each of the two rotating portions 75 extends through each of the two mounting slots 137, to engage each of the two pivoting posts 1353 in each of the two rotating holes 751. Therefore, the bezel 30 is rotatably attached to the front panel 13.

Each of the two clasping members 50 is located between each pair of the two pairs of positioning pieces 133, and the two fixing holes 513 are aligned with the two first mounting holes 136. Two fixing members (not shown), such as screws, are engaged in the two fixing holes 513 and the two first mounting holes 136, and the clasping member 50 is secured to the front panel 13. At this point, the receiving opening 511 communicates with the through hole 134.

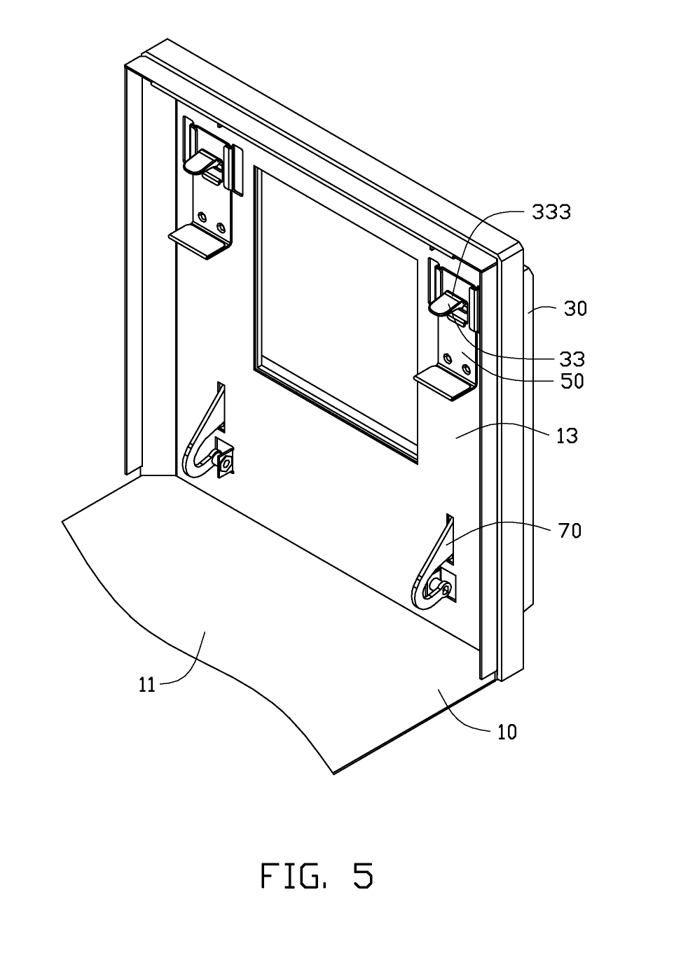

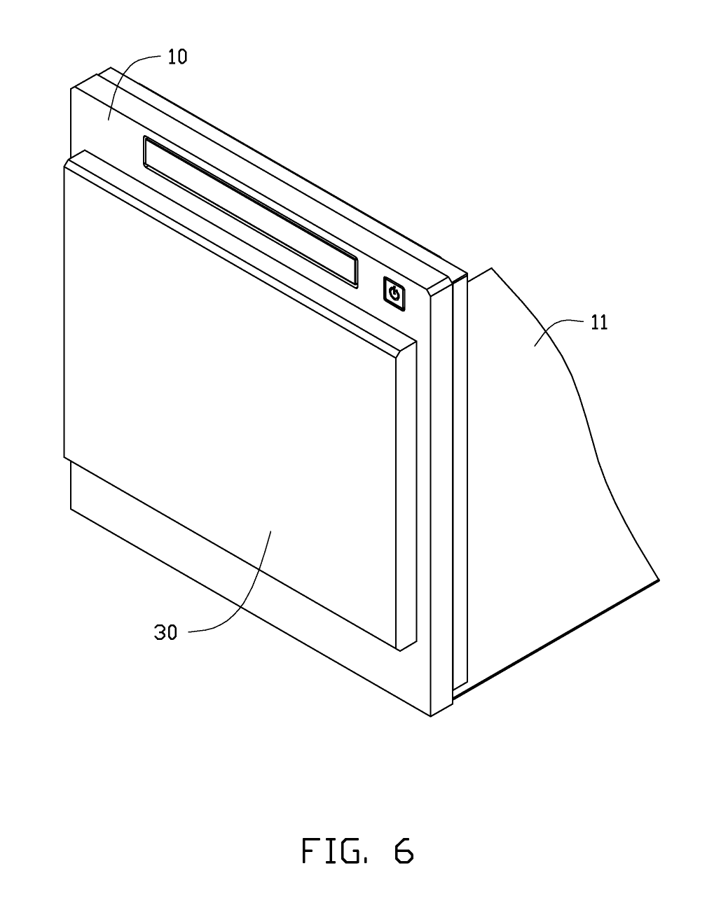

FIGS. 5-6, the bezel 30 is rotated toward the front panel 13, each of the two clipping portions 33 extends through two through holes 134 and the two receiving openings 511, and the first clipping surface 3331 is locked with the first edge 5111. The bezel is secured to the base 10. When the bezel 30 is needed to be opened, the two clipping portions 33 are pressed downward from an inner side of the base 10, to the first clipping surface 3331, which is detached from the first edge 5111. The bezel 30 can thus be rotated away from the front panel 13.

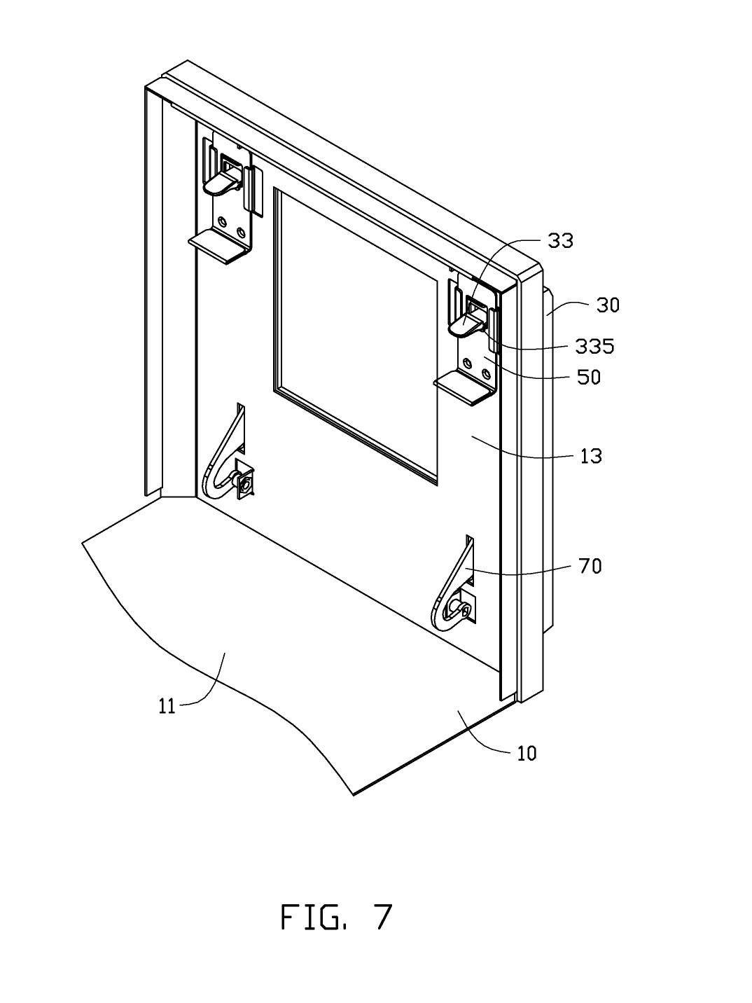

FIG. 7 shows that in assembly, each of the two clasping members 50 is located between each of the two pairs of positioning pieces 133, and the two fixing holes 513 are aligned with the two second mounting holes 138, not the two first mounting holes 136. Two fixing members (not shown), such as screws, are engaged in the two fixing holes 513 and the two second mounting holes 138, and the clasping member 50 is secured to the front panel 13. When the bezel 30 is rotated towards the front panel 13, each of the two clipping portions 33 extends through two through holes 134 and the two receiving openings 511, and the second clipping surface 3351 is clipped to the second edge 5113. When opening the bezel 30, the bezel 30 is rotated away from the front panel 13 driven by the outside bezel 30. As the second clipping surface 3351 is arcuate, the second clipping surface 3351 extends through the second edge 5113, until the second hook 335 is moved towards the center of the receiving opening 511 to disengage from the receiving opening 511 when the bezel 30 is rotated. The bezel 30 is further rotated away from the front panel 13 and can be opened.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device enclosure comprising:
a base comprising a front panel; a through hole defined in the front panel;
a bezel comprising a clipping portion; the clipping portion comprising a connecting arm extending from the bezel, a first hook, and a second hook; and the first hook and the second hook protruding opposite sides of from the connecting arm;
a clasping member defining a receiving opening communicating with the through hole; the receiving opening comprising a first edge and a second edge opposite to the first edge;
wherein the clipping portion extends through the through hole and the receiving opening, the clasping member is located relative to the front panel in a first position or a second position different from the first position; when the clasping member is in the first position, the first hook is engaged with the first edge; and when the clasping member is in the second position, the second hook is engaged with the second edge.

2. The electronic device enclosure of claim 1, wherein the first hook comprises a first clipping surface, and the first clipping surface abuts the first edge when the clasping member is in the first position.

3. The electronic device enclosure of claim 1, wherein the second hook comprises a second clipping surface, and the second clipping surface is substantially arcuate; and when the clasping member is in the second position, the second clipping surface abuts the second edge.

4. The electronic device enclosure of claim 1, wherein the front panel comprises a main body and two positioning pieces extending from the front panel, and the clasping member is located between the two positioning pieces.

5. The electronic device enclosure of claim 4, wherein the clasping member comprises a mounting piece and an operating portion connected to the mounting piece; the receiving opening is defined in the mounting piece, the mounting piece is located between the two positioning pieces, and the operating portion is adapted to move the clasping member between the first position and the second position.

6. The electronic device enclosure of claim 1, wherein the bezel is rotatably attached to the front panel.

7. The electronic device enclosure of claim 6, further comprising a rotating member; wherein the rotating member comprises a securing piece and a rotating portion, the securing piece is attached to the bezel, the front panel comprises a pivoting portion, and the pivoting portion is rotatably engaged with the rotating portion.

8. The electronic device enclosure of claim 7, wherein the rotating member further comprises a connecting portion, connected to the securing piece and the rotating portion, and the connecting portion is substantially perpendicular to the securing piece.

9. The electronic device enclosure of claim 8, wherein the front panel defines a mounting slot above the pivoting portion, and the rotating portion extends through the mounting slot to rotatably engage with the pivoting portion.

10. An electronic device enclosure comprising:
a base comprising a front panel; a through hole defined in the front panel;
a bezel attached to an outer surface of the front panel, the bezel comprising a clipping portion extending through the through hole and the receiving opening; the clipping portion comprising a first hook and a second hook;
a clasping member attached to an inner surface of the front panel, the clasping member defining a receiving opening communicating with the through hole; the receiving opening comprising a first edge and a second edge opposite to the first edge;
wherein the first hook is engaged with the first edge when the clasping member is secured to the front panel in a first position, and the second hook is engaged with the second edge when the clasping member is secured to the front panel in a second position different from the first position.

11. The electronic device enclosure of claim 10, wherein the clipping portion further comprises a connecting arm; the first hook and the second hook protrude from opposite sides of the connecting arm.

12. The electronic device enclosure of claim 10, wherein the first hook comprises a first clipping surface, and the first clipping surface abuts the first edge when the clasping member is in the first position.

13. The electronic device enclosure of claim 10, wherein the second hook comprises a second clipping surface, and the second clipping surface is substantially arcuate; and when the clasping member is in the second position, the second clipping surface abuts the second edge.

14. The electronic device enclosure of claim 10, wherein the front panel comprises a main body and two positioning pieces extending from the front panel, and the clasping member is located between the two positioning pieces.

15. The electronic device enclosure of claim 14, wherein the clasping member comprises a mounting piece and an operating portion connected to the mounting piece; the receiving opening is defined in the mounting piece, the mounting piece is located between the two positioning pieces, and the operating portion is adapted to move the clasping member between the first position and the second position.

16. The electronic device enclosure of claim 10, wherein the bezel is rotatably attached to the front panel.

17. The electronic device enclosure of claim 16, further comprising a rotating member; wherein the rotating member comprises a securing piece and a rotating portion, the securing piece is attached to the bezel, the front panel comprises a pivoting portion, and the pivoting portion is rotatably engaged with the rotating portion.

18. The electronic device enclosure of claim 17, wherein the front panel defines a mounting slot above the pivoting portion, and the rotating portion extends through the mounting slot to rotatably engage with the pivoting portion.

19. The electronic device enclosure of claim 10, wherein a fixing hole is defined in the clasping member; the front panel defines a first mounting hole and a second mounting hole above the first mounting hole; when the clasping member is in the first position, the first mounting hole is aligned with the fixing hole, a fixing member is engaged in the first mounting hole and the fixing hole to secure the clasping member to the front panel; when the clasping member is in the second position, the second mounting hole is aligned with the fixing hole, the fixing member is engaged in the second mounting hole and the fixing hole to secure the clasping member to the front panel.
